(19) United States
(12) Patent Application Publication
(10) Pub. No.: US 2017/0148682 A1
(43) Pub. Date: May 25, 2017

(54) FINFET WITH POST-RMG GATE CUT

(71) Applicant: International Business Machines Corporation, Armonk, NY (US)

(72) Inventors: Veeraraghavan S. Basker, Schenectady, NY (US); Kangguo Cheng, Schenectady, NY (US); Theodorus E. Standaert, Clifton Park, NY (US); Junli Wang, Singerlands, NY (US)

(21) Appl. No.: 14/946,057

(22) Filed: Nov. 19, 2015

(51) Int. Cl. H01L 21/8234; H01L 21/762; H01L 29/06; H01L 21/3213; H01L 27/088

(52) U.S. Cl. CPC H01L 21/823431; H01L 21/823437; H01L 21/823481; H01L 21/32133; H01L 27/0886; H01L 29/0649; H01L 21/76224

(57) ABSTRACT

In a FinFET device, the gate cut is performed post-RMG. This allows PC-past-RX to be scaled to the thickness of the gate stack, thus reducing PC end parasitic capacitance and improving device performance. Specifically, the gate stack integration is completed first, and then the gates are cut using a lithographically-defined CT mask and selective etching of the gate stack metals, and optically the gate dielectric. The selective etch allows the cut to be located as close as possible to the fins without adversely affecting source and drain epitaxial doping layers, even when the cut opening overlaps with the epitaxial layers.

### BACKGROUND

The present application relates generally to semiconductor device structures and their methods of manufacture, and more specifically to FinFET architectures having reduced parasitic capacitance and uniform work function.

As the number of devices per chip increases, both inter and intra device dimensions decrease. Each successive generation of design rules are challenged to deliver processability without compromising function. The pursuit within the semiconductor industry of high density, high performance, and low cost devices and the attendant implementation of nanometer-scale process nodes have resulted in the development of three-dimensional (3D) architectures such as a fin-shaped field effect transistor (FinFET).

Within a typical FinFET, the channel between the source and the drain is formed as a raised fin over a substrate. The gate electrode is then formed over the sidewalls and top of the channel. Compared to traditional (planar) metal oxide semiconductor field effect transistors (MOSFETs), the three-dimensional gate structure associated with the FinFET provides better electrical control over the channel, which helps decrease leakage current and minimize other short-channel effects.

Even within 3D designs, there is a need for efficient integration. For example, in a FinFET it would be beneficial to locate respective gate ends closer to the fins, i.e., decrease the gate end-to-fin spacing (PC-past-RX) and thus decrease the associated parasitic capacitance. It would therefore be beneficial to develop a process flow to accomplish the foregoing while not otherwise adversely affecting device performance.

### SUMMARY

In accordance with embodiments of the present application, a method of forming a semiconductor structure is provided. In one embodiment, the method includes depositing a gate structure over respective portions of adjacent parallel fins disposed on a substrate, the gate structure including a gate dielectric formed over the fins and a gate electrode formed over the gate dielectric. A conductive material is then deposited over the gate electrode. Next, the conductive material, the gate electrode, and optionally the gate dielectric are selectively etched to form a gate cut region between a pair of the adjacent fins. A dielectric material is thereafter deposited into the gate cut region to form an isolation region.

In a related method, a semiconductor structure can be formed by providing a gate structure disposed over respective portions of adjacent parallel fins disposed on a substrate. The gate structure includes a gate dielectric formed over the fins and a gate electrode formed over the gate dielectric. Further, a conductive material may be disposed over the gate electrode. The structure may be formed by selectively etching the conductive material, the gate electrode, and optionally the gate dielectric to form a gate cut region between a pair of the adjacent fins, and depositing a dielectric material into the gate cut region to form an isolation region.

A semiconductor structure made in accordance with embodiments of the application includes a plurality of fins disposed on a substrate, and a gate structure formed over respective portions of adjacent parallel fins. The gate structure includes a gate dielectric formed over the fins, a gate electrode formed over the gate dielectric, and a conductive material formed over the gate electrode. The semiconductor structure includes an isolation region formed from a dielectric material located between a pair of the adjacent fins. In the semiconductor structure, a distance from the isolation region to at least one of the adjacent fins is less than 30 nm.

### BRIEF DESCRIPTION OF SEVERAL VIEWS OF THE DRAWINGS

The following detailed description of specific embodiments of the present application can be best understood when read in conjunction with the following drawings, where like structure is indicated with like reference numerals and in which:

FIG. 1 is a schematic diagram of a conventional FinFET device with metal gate stack and gate dielectric materials deposited over both gate spacers and fins;

FIG. 2 is a schematic diagram of a FinFET device according to embodiments where the metal gate stack and gate dielectric materials are deposited over only the fins;

FIGS. 3A and 3B are perspective and plan views showing planarization of a sacrificial gate, sidewall spacers, and interlayer dielectric over a plurality of parallel fins;

FIGS. 4A and 4B show removal of the sacrificial gate to form a gate cavity;

FIGS. 5A and 5B show conformal deposition of a gate dielectric within the gate cavity over the fins and the sidewall spacers;

FIGS. 6A and 6B show conformal deposition of a metal gate stack in contact with the gate dielectric;

FIGS. 7A and 7B show deposition and planarization of a metal conductive layer;

FIGS. 8A and 8B show the deposition and patterning of a cut mask;

FIGS. 9A and 9B show the selective etching of the gate metals to form a gate cut region after removal of the cut mask;

FIGS. 10A and 10B show the deposition and planarization of a gate spacer within the gate cut region;

FIGS. 11A and 11B are perspective and plan view images according to a further embodiment showing formation of the gate cut region and recessing of the gate stack; and

FIGS. 12A and 12B show the structure of FIG. 11 after the simultaneous deposition and subsequent planarization of a gate spacer within the gate cut region and a gate cap layer over the gate electrode.

### DETAILED DESCRIPTION

Reference will now be made in greater detail to various embodiments of the subject matter of the present application, some embodiments of which are illustrated in the accompanying drawings. The same reference numerals will be used throughout the drawings to refer to the same or similar parts.

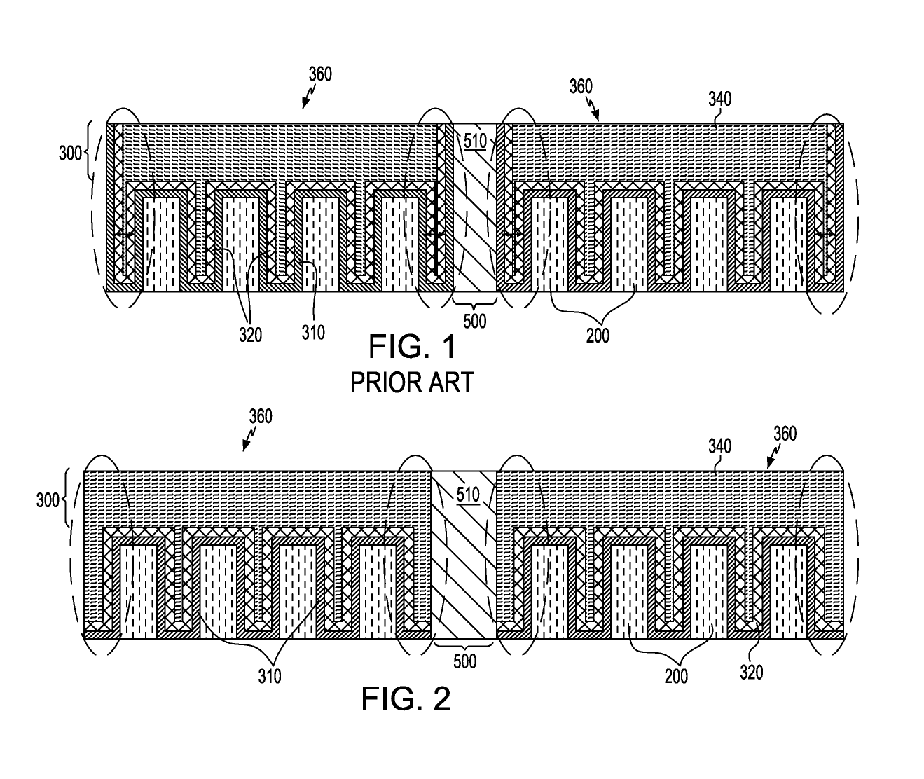

As design rules for semiconductor devices extend below 32 nm, the minimization of parasitic capacitance is increasingly important to performance. In particular, for state-of-the-art FinFET devices, gate end-to-fin parasitic capacitance is inadequately scaled because the gate dielectric and gate metal layers coat the PC sidewalls as well as the fins. This can be seen with reference to FIG. 1.

FIG. 1 is a cross-sectional schematic showing plural fins 200 with conformal layers of a gate dielectric 310 and gate electrode 320 deposited over the fins 200. Formed over the gate electrode 320 is a planarized conductive material 340 such as a tungsten layer. The gate dielectric 310 and gate electrode 320 define a gate stack 300. The gate electrode 320 may include one or more conductive layers such as a work function metal and a liner. Not shown for clarity is an epitaxial (doping) layer that is optionally formed over the fins 200 prior to depositing the gate stack 300.

The term “epitaxial” as used herein means the formation of a semiconductor material on a deposition surface of a semiconductor material where the material being formed has the same crystalline characteristics as the material of the deposition surface. In an epitaxial deposition process, chemical reactants provided by source gases for the layer to be formed are controlled, and the system parameters are set so that the depositing atoms arrive at the deposition surface of the semiconductor substrate with sufficient energy to diffuse on the surface and orient themselves to the crystal arrangement of the atoms of the deposition surface. Therefore, an epitaxial semiconductor material has the same crystalline orientation as the deposition surface on which it is formed. For example, an epitaxial semiconductor material deposited on a {100} crystal surface will take on a {100} orientation. Separating adjacent gate regions 360 at respective line ends is a gate cut region 500 shown filled with a dielectric gate spacer 510. Gate spacer 510 provides electrical isolation between adjacent gate segments and with respect to the fins outside the gate. As can be seen within the circled regions of FIG. 1, the conformal gate dielectric 310 and gate electrode 320 are formed over a sidewall of the gate spacer 510 as well as over fins 200.

In order to form a functional gate structure over each fin, the minimum spacing from the gate cut region 500 to the nearest fin wall (PC-past-RX) is at least twice the thickness of the gate dielectric and gate electrode layers in order to avoid pinch off at the line end. For instance, for an example architecture comprising a 1.5 nm thick layer of (high-k) dielectric, a 5 nm thick gate stack (e.g., 1 nm TiN/3 nm TiC/1 nm TiN), and a 4 nm thick layer of work function metal/liner, the minimum spacing of PC-past-RX is 21 nm (=2[1.5+5+4]) to accommodate deposition of all the layers. In addition to this, there is a minimal overlay and critical dimension tolerance, which makes the minimum PC-past-RX typically about 28 nm. This distance is depicted in FIG. 1 with double-headed arrows. As used herein, a “high-k” dielectric material has a dielectric constant greater than that of silicon oxide. A “functional gate structure” as used herein refers to a permanent gate structure used to control output current (i.e., the flow of carriers in the channel) of a semiconductor device through electric or magnetic fields.

In contrast, the presently-disclosed manufacturing method can locate the gate end of the FinFET architecture substantially closer to the fins. Moreover, relocation of the gate end closer to the fin edge is accomplished without adversely affecting work function or disruption of the epitaxial (doping) layer formed over the fins.

According to various methods, disclosed is a replacement metal gate FinFET structure where the line ends of the device are cut and the wall of the gate end is formed after deposition of the gate dielectric and conductive gate electrode. As a result, the gate dielectric and gate metal layers are not deposited on the gate spacer 510. This enables a more aggressive gate end-to-fin geometry (i.e., ˜1× as opposed to −2× the gate dielectric+gate electrode thickness). A FinFET architecture according to embodiments is shown in FIG. 2.

FIG. 2 is a cross-sectional schematic showing plural fins 200 with conformal layers of a gate dielectric 310 and gate electrode 320 deposited over the fins 200. Not shown for clarity is an epitaxial (doping) layer that may be formed over the fins prior to depositing the gate stack 300. Formed over the gate electrode 320 is a planarized conductive layer 340 such as a tungsten.

Separating adjacent gate regions 360 at respective line ends is a gate cut region 500 shown filled with a dielectric gate spacer 510. As can be clearly seen within the circled regions of FIG. 2, the conformal gate dielectric 310 and gate electrode 320 are not formed over a sidewall of the gate spacer 510. Thus, for an exemplary gate stack comprising a 1.5 nm thick layer of (high-k) dielectric, a 5 nm thick gate stack (e.g., 1 nm TiN/3 nm TiC/1 nm TiN), and a 4 nm thick layer of work function metal, the minimum spacing of PC-past-RX is 10.5 nm to accommodate deposition of all the layers. With the required overlay and critical dimension tolerance, PC-past-RX can be scaled to 15 nm. This represents an almost 50% decrease compared to comparative structures where these layers are deposited over a sidewall of the gate spacer.

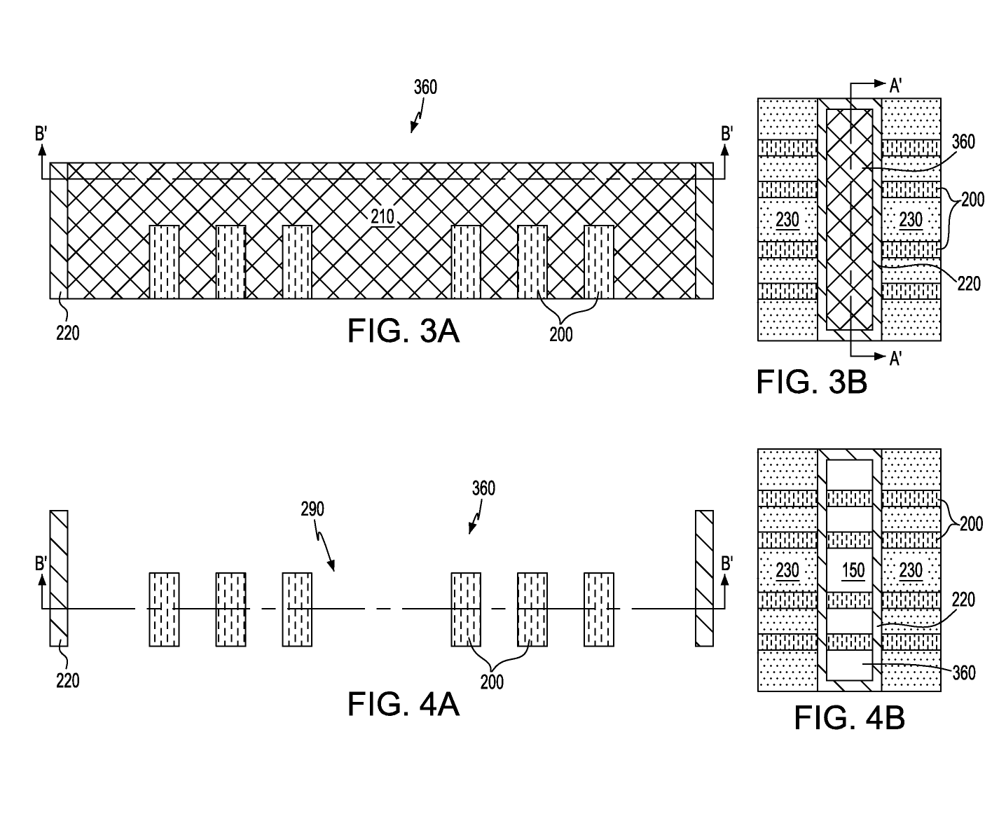

Various embodiments for manufacturing a FinFET device are depicted in FIGS. 3-12. Illustrated in FIGS. 3-10 are select steps within the process flows according to one embodiment.

With reference to FIG. 3, fins 200 may be formed on a substrate (not shown) such as a semiconductor substrate. In one embodiment, the semiconductor substrate is a semiconductor-on-insulator (SOI) substrate including, from bottom to top, a handler substrate, an insulator layer and a semiconductor material layer. In some embodiments, the handler substrate can be omitted. In other embodiments, a bulk substrate (not shown) can also be used where an insulator layer can be omitted.

In some embodiments, the handler substrate and the semiconductor material layer of an SOI substrate may comprise the same semiconductor material. In other embodiments, the handler substrate and the semiconductor material layer of the SOI substrate may comprise different semiconductor materials.

The term “semiconductor” as used herein denotes any semiconducting material including, for example, Si, Ge, SiGe, SiC, SiGeC, and III-V compound semiconductors such as InAs, GaAs and InP. Multi-layers of these semiconductor materials can also be used, for example, as the semiconductor material of the handler substrate and the semiconductor material layer. In one embodiment, the handler substrate and the semiconductor material layer are both comprised of silicon. In some embodiments, the handler substrate is a non-semiconductor material such as a dielectric material and/or a conductive material.

In an SOI substrate, the handler substrate and the semiconductor material layer may have the same or different crystal orientation. For example, the crystal orientation of the handler substrate and/or the semiconductor material layer may be {100}, {110}, or {111}. Other crystallographic orientations besides those specifically mentioned can also be used.

The handler substrate and/or the semiconductor material layer of the SOI substrate may be a single crystalline semiconductor material, a polycrystalline material, or an amorphous material. Typically, the semiconductor material layer is a single crystalline semiconductor material.

The insulator layer of an SOI substrate may be a crystalline or a non-crystalline oxide or nitride. In one embodiment, the insulator layer is an oxide such as, for example, silicon dioxide. The insulator layer may be continuous or discontinuous.

An SOI substrate may be formed using processes known to those skilled in the art, including for example, a SIMOX (separation by ion implantation of oxygen) process or a layer transfer process.

The thickness of the semiconductor material layer of an SOI substrate may be 10 nm to 100 nm, with a thickness from 50 nm to 70 nm being more typical. In some embodiments, such as when an ETSOI (extremely thin semiconductor-on-insulator) substrate is used, the semiconductor material layer of the SOI substrate can have a thickness of less than 10 nm. If the thickness of the semiconductor material layer is not within one of the above mentioned ranges, a thinning step such as, for example, planarization or etching can be used to reduce the thickness of semiconductor material layer to a value within a desired range. The insulator layer of the SOI substrate may have a thickness from 1 nm to 200 nm, with a thickness from 100 nm to 150 nm being more typical.

The semiconductor material layer may be doped, undoped, or contain doped and undoped regions therein. Each doped region within the semiconductor material layer may have the same or different conductivities and/or doping concentrations. Doped regions that are present in the semiconductor material layer can be formed, for example, by an ion implantation process or by gas phase doping.

A patterning process may be used to define the fins 200. The patterning process may comprise lithography and etching. Lithography includes forming a layer of photoresist material atop a material or material stack to be patterned. The photoresist material may include a positive-tone photoresist, a negative-tone photoresist or a hybrid-tone photoresist. A layer of photoresist may be formed by a deposition process such as, for example, spin-on coating.

The deposited layer of photoresist material is subjected to a pattern of irradiation. Then the exposed photoresist is developed utilizing a resist developer. This provides a patterned photoresist layer atop the layer(s) to be patterned. The pattern provided by the photoresist material is thereafter transferred into the underlying layer(s) using at least one pattern transfer etching process. Typically, the at least one pattern transfer etching process is an anisotropic etch. In one embodiment, a dry etching process such as, for example, reactive ion etching can be used to form the fins. In another embodiment, a chemical etchant can be used. In still a further embodiment, a combination of dry etching and wet etching can be used.

In an alternative approach, the patterning process may include a sidewall image transfer (SIT) process. The SIT process includes forming a mandrel material layer atop the material or material layers that are to be patterned. The mandrel material layer can include any material (semiconductor, dielectric or conductive) that can be selectively removed from the structure during a subsequently performed etching process. For example, the mandrel material layer may be composed of amorphous silicon or polysilicon. In another example, the mandrel material layer may be composed of a metal such as Al, W or Cu.

The mandrel material layer can be formed, for example, by chemical vapor deposition or plasma enhanced chemical vapor deposition. Following deposition of the mandrel material layer, the mandrel material layer is patterned, for example, by lithography and etching to form a plurality of mandrel structures on the topmost surface of the structure.

The SIT process continues by forming a dielectric spacer on the sidewalls of each mandrel structure. The dielectric spacer can be formed by deposition of a dielectric spacer material and then etching the deposited dielectric spacer material. The dielectric spacer material may comprise any dielectric spacer material such as, for example, silicon dioxide, silicon nitride or a dielectric metal oxide.

Examples of deposition processes that can be used to form the dielectric spacer material include, for example, chemical vapor deposition (CVD), plasma enhanced chemical vapor deposition (PECVD), or atomic layer deposition (ALD). Examples of etching that be used in providing the dielectric spacers include any etching process such as, for example, reactive ion etching.

After formation of the dielectric spacers, the SIT process continues by removing each mandrel structure. Each mandrel structure can be removed by an etching process that is selective for removing the mandrel material. Following the mandrel structure removal, the SIT process continues by transferring the pattern provided by the dielectric spacers into the underlying material or material layers. The pattern transfer may be achieved by utilizing at least one etching process. Examples of etching processes that can used to transfer the pattern may include dry etching (i.e., reactive ion etching, plasma etching, and ion beam etching or laser ablation) and/or wet chemical etching. In one example, the etch process used to transfer the pattern may include one or more reactive ion etching steps.

Upon completion of the pattern transfer, the SIT process concludes by removing the dielectric spacers from the structure. Each dielectric spacer may be removed by etching or a planarization process.

In embodiments, fins 200 are formed by etching into a substrate and removing substrate material from between the fins. As used herein, a “fin” refers to a contiguous semiconductor material such as silicon that includes a pair of tapered or substantially vertical sidewalls that are parallel to each other.

In one embodiment of the present application, each fin 200 has a height of 10 nm to 100 nm and a width of 4 nm to 30 nm. Other heights and widths that are less than or greater than the aforementioned ranges can also be used in the present application. In embodiments, each fin 200 is spaced apart from its nearest neighboring fin 200 by a pitch of 20 nm to 100 nm. Plural fins may be arranged parallel to each other.

FIGS. 3A and 3B are cross-sectional and plan view images, respectively, showing a sacrificial gate 210 and sidewall spacers 220 deposited over fins 200 within gate region 360. As seen in FIG. 3B, the sacrificial gate 210 is oriented orthogonal to and straddles each fin 200. An interlayer dielectric 230 is formed over the plurality of fins 200 within source and drain regions 370, 380. The sacrificial gate 210 and interlayer dielectric 230 are planarized to the height of the sidewall spacers 220. The cross-sectional view in FIG. 3A is taken across the gate region 360 along line A′-A′.

By “sacrificial gate” is meant a material or a material stack that serves as a placeholder for a subsequently formed functional gate structure. The sacrificial gate 210 can comprise polycrystalline silicon, polycrystalline germanium or a polycrystalline silicon-germanium alloy. The sidewall spacers 220 can comprise a dielectric material such as, for example, silicon oxide, silicon carbon nitride, silicon oxycarbon nitride, silicon boron-carbon nitride or silicon nitride. The interlayer dielectric 230 can comprise silicon oxide (SiO₂) or silicon oxynitride (SiOₓN_{y}).

FIGS. 4A and 4B show removal of the sacrificial gate 210 to exposure fins 200 and substrate 150 within the gate region 360. The top-down view in FIG. 4B (as well as in FIGS. 6B-12B) is taken along respective line B′-B′. It should be noted that while six fins are shown in the cross-sectional views of FIGS. 3-12, only four fins are shown in the corresponding top-down views for clarity.

The sacrificial gate 210 can be removed selective to fins 200, spacers 220 and interlayer dielectric 230 using, for example, a wet chemical etch such as an ammonia-containing etch or a dry etch such as reactive ion etching. Gate cavities 290 are laterally confined by inner sidewalls of the spacers 220. As described in further detail below, a functional gate structure is then formed over a portion of the fins within each cavity 290.

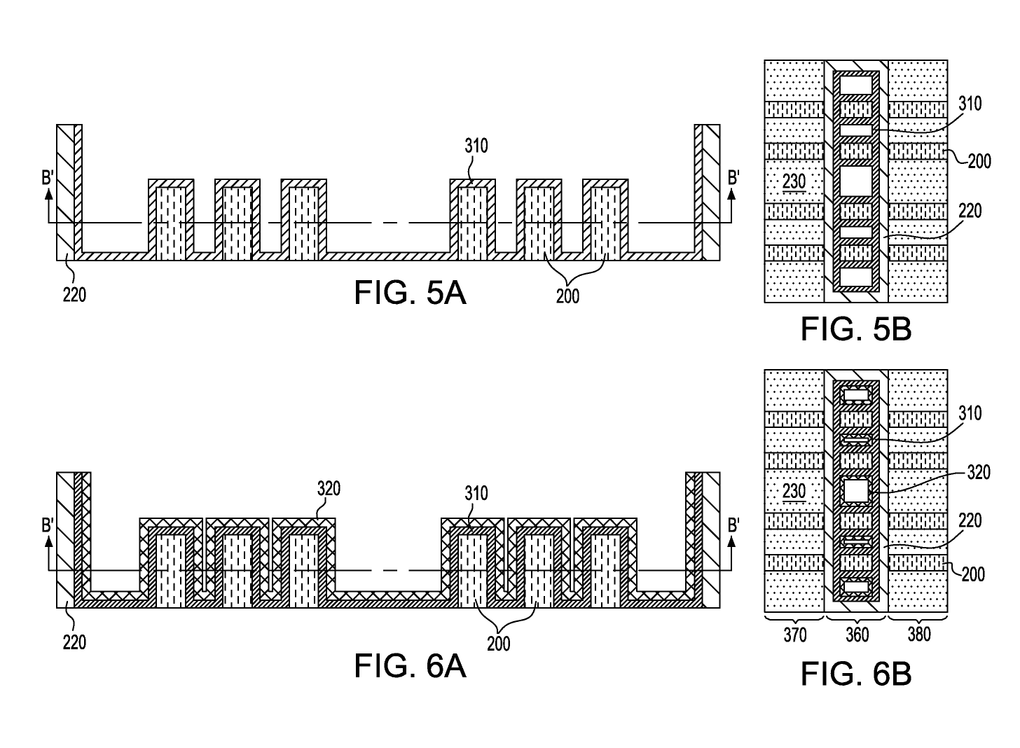

As depicted in the following figures, each functional gate structure includes, from bottom to top, a gate dielectric 310, a gate electrode 320, and a conductive material 340. FIGS. 5A and 5B show conformal deposition of a gate dielectric 310 over the fins 200 and the sidewall spacers 220. The gate dielectric 310 may include silicon oxide, silicon nitride, a high-k dielectric, or other suitable material. A high-k dielectric may include a binary or ternary compound such as hafnium oxide. Further exemplary high-k dielectrics include, but are not limited to, ZrO₂, La₂O₃, Al₂O₃, TiO₂, SrTiO₃, BaTiO₃, LaAlO₃, Y₂O₃, HfOₓN_{y}, ZrOₓN_{y}, La₂OₓN_{y}, Al₂OₓN_{y}, TiOₓN_{y}, SrTiOₓN_{y}, LaAlOₓN_{y}, Y₂OₓN_{y}, SiOₓN_{y}, SiNₓ, a silicate thereof, and an alloy thereof. Each value of x is independently from 0.5 to 3 and each value of y is independently from 0 to 2.

The gate dielectric 310 may be deposited by a suitable process such as atomic layer deposition (ALD), chemical vapor deposition (CVD), physical vapor deposition (PVD), thermal oxidation, UV-ozone oxidation, or combinations thereof. The gate dielectric thickness may range from 1 nm to 10 nm.

FIGS. 6A and 6B show conformal deposition of a gate electrode 320 in contact with the gate dielectric 310. The gate electrode may include polysilicon, silicon-germanium, a conductive metal, or a conductive metal compound such as Ti, TiN, TiC, TiSiN, TiTaN, Ta, TaN, TaSiN, TaRuN, W, WSiN, NiSi, CoSi, as well as combinations thereof. The gate electrode 320 may comprise one or more layers of such materials such as, for example, a metal stack including a work function metal layer and/or a liner. The gate electrode can be deposited using CVD, sputtering, or plating and may have a thickness ranging from 1 nm to 10 nm, e.g., 2 nm to 5 nm.

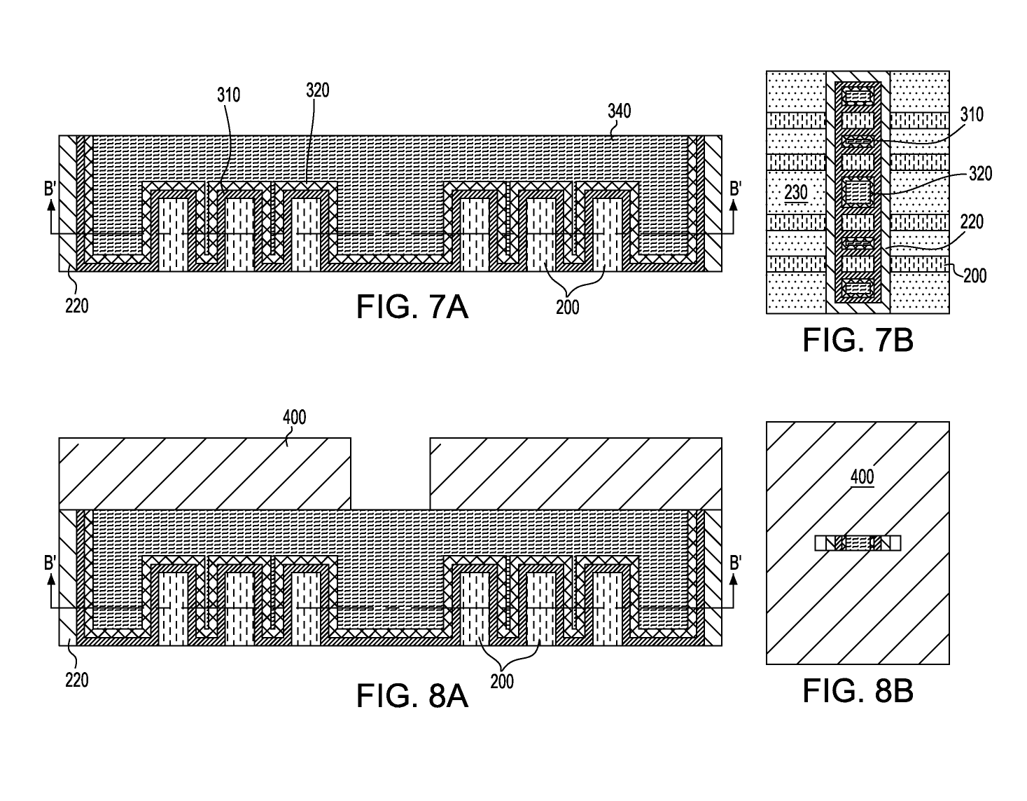

FIGS. 7A and 7B show deposition and planarization of a conductive material 340. The conductive material 340 may include, for example, Al, W, Cu, Pt, Ag, Au, Ru, Ir, Rh and Re, alloys of conductive metals, e.g., Al—Cu, silicides of a conductive metal, e.g., W silicide, and Pt silicide, and combinations thereof. The layer of conductive material can be formed utilizing a conventional deposition process such as, for example, atomic layer deposition (ALD), CVD, metalorganic chemical vapor deposition (MOCVD), molecular beam epitaxy (MBE), PVD, plating, evaporation, ion beam deposition, electron beam deposition, laser assisted deposition, and chemical solution deposition.

A portion of the material stack of the gate dielectric material, the gate electrode, and the conductive material is then removed by employing a planarization process, for example, chemical mechanical planarization (CMP). As such and as shown in FIG. 7A, uppermost surfaces of each of the gate dielectric 310, the gate electrode 320, and the conductive material 340 are coplanar with the dielectric spacers 220 after planarization. The thickness of gate electrode 320 may range from 1 nm to 100 nm.

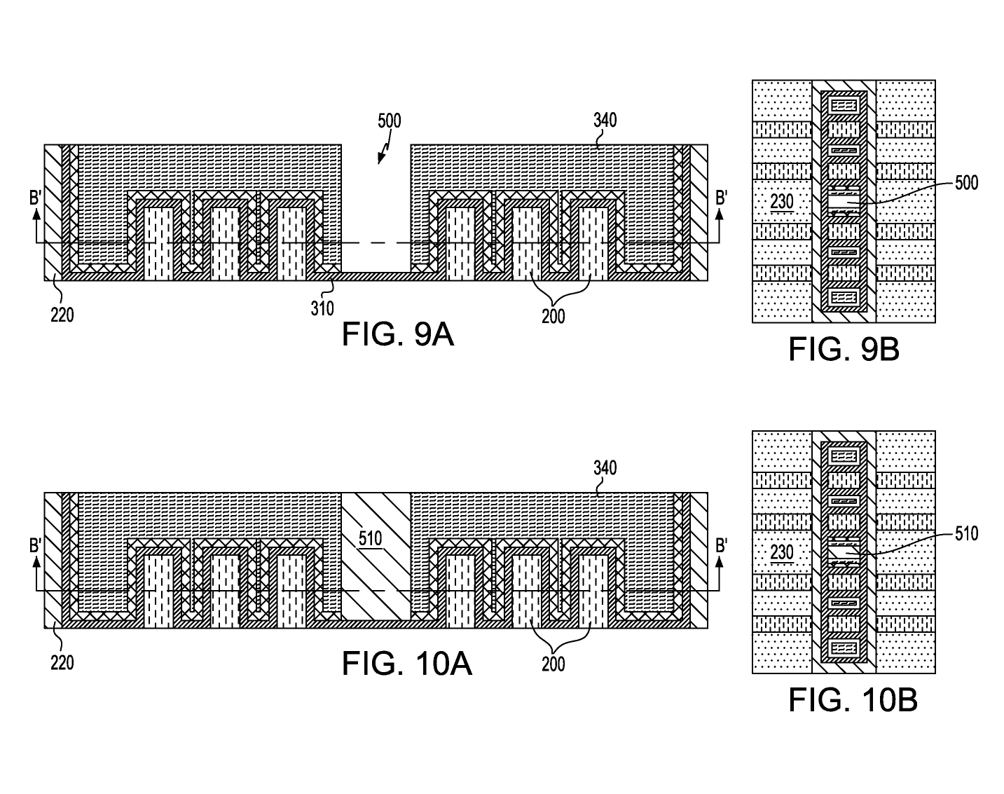

FIGS. 8A and 8B show the deposition and patterning of a cut (CT) mask 400. Cut mask 400 is used to define a gate cut region 500 and cut the gate electrode 320 into the desired pattern. As seen with reference particularly to the projected top-down view of FIG. 8B, multiple layers of the device architecture are aligned with the gate cut region 500 defined by cut mask 400. However, as seen with reference to FIGS. 9A and 9B, only the gate electrode 320 and the conductive material 340 (and optionally the gate dielectric 310 are etched). That is, the gate cut etch is selective to the interlayer dielectric 230 within the source and drain regions, the dielectric spacer 220, as well as the epitaxial doping layer that is formed over the fins 200. FIGS. 9A and 9B show the selective etching of the gate electrode materials after removal of the cut mask 400. In the illustrated embodiment, the gate dielectric 310 is exposed within the gate cut region 500. In an alternate embodiment, the gate dielectric 310 within the gate cut region 500 can be removed during etching of the gate electrode 320 or in a successive etch process.

The cut mask 400 may comprise a photoresist layer that is deposited over the functional gate structure and the interlayer dielectric and then patterned using conventional lithography. In one embodiment, the photoresist is exposed to a desired pattern of radiation and then, using a resist developer to develop exposed portions of the photoresist, openings are selectively formed in the photoresist layer exposing portions of the functional gate structure that will be removed subsequently. The particular circuit design determines which portions of the functional gate structure are removed to form a gate cut region 500.

Still with reference to FIG. 9, illustrated is an exemplary structure after removing exposed portions of the gate electrode 320. Exposed portions of the gate stack, including the gate dielectric, can be removed selective to the fins 200, spacers 220, and interlayer dielectric 230 using wet chemical etching and/or dry etching. In some embodiments, a RIE process can be used to etch the conductive material 340 down to the gate electrode. A further wet etch can be used to further remove the gate electrode and optionally the gate dielectric to form gate cut region 500. An example wet etch may comprise HCl or HF, for example. After removing the exposed portions of the functional gate structure, the photoresist can be removed using a conventional photoresist stripping process such as ashing.

FIGS. 10A and 10B show the deposition and planarization of a gate spacer 510 within gate cut region 500. The gate spacer 510 may comprise a dielectric spacer material such as, for example, silicon dioxide, silicon nitride or a dielectric metal oxide. Examples of deposition processes that can be used to form the gate spacer material include, for example, chemical vapor deposition (CVD), plasma enhanced chemical vapor deposition (PECVD), or atomic layer deposition (ALD).

The gate spacer 510 can be formed by depositing a blanket layer of dielectric material and then planarizing the gate spacer 510 via CMP to recess the top of the gate spacer to approximately the same height as the interlayer dielectric 230 and the functional gate structure. In embodiments where etching the gate cut region 500 removes the conductive material 340 and the gate electrode 320 and stops on the gate dielectric 310, the gate spacer 510 is formed over the exposed sidewalls of the conductive material of adjacent gates, over the exposed surface of the gate dielectric 310 at the bottom of the gate cut region, and over only the exposed edges of the gate electrode 320 of adjacent gates (see FIG. 10A).

In embodiments where etching the gate cut region 500 removes the conductive material 340, the gate electrode 320, and the gate dielectric 310, the gate spacer 510 is formed over the exposed sidewalls of the conductive material of adjacent gates, over the exposed surface of the substrate 150 at the bottom of the gate cut region, and over only the exposed edges of the gate electrode 320 and gate dielectric 320 of adjacent gates.

In embodiments, PC-past-RX is less than 30 nm, e.g., 8, 10, 12, 15, 20 or 25 nm, including ranges between any of the foregoing. Such close proximity of the gate ends to the fins is enabled in part by the post-replacement metal gate (RMG) gate cut, which obviates deposition of gate electrode materials on the sidewalls of the gate cut regions. Further, the use of a selective etch to define the gate cut region allows the cut to be located as close as possible to the fins without adversely affecting source and drain epitaxial doping layers, even when the cut opening overlaps with the epitaxial layers.

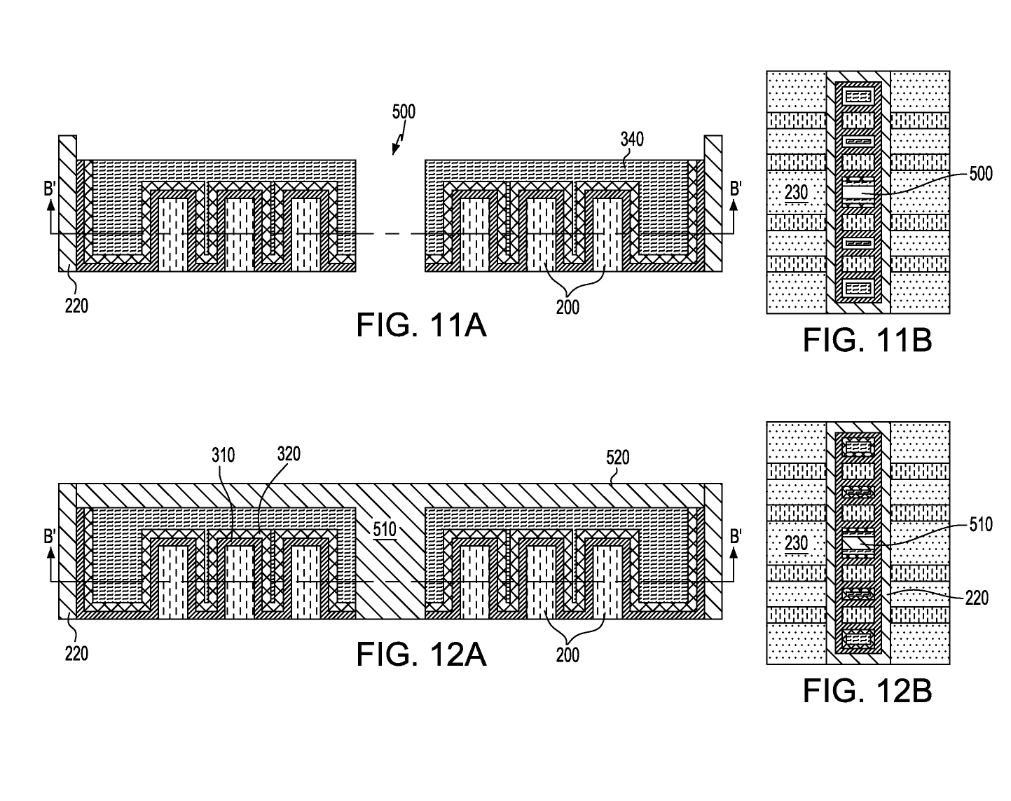

Illustrated in FIGS. 11 and 12 are select steps within a process flow for manufacturing a FinFET device according to a further embodiment.

In FIG. 11, gate cut region 500 is formed by etching through conductive material 340, gate electrode 320 and, in the current embodiment, gate dielectric 310. Also, in the illustrated embodiment the top surfaces of each of the conductive material 340, gate electrode 320, and gate dielectric 310 are substantially co-planar and recessed with respect to spacers 220. In alternate embodiments, conductive material 340 and gate electrode 320 may be recessed to a common height that is lower than the gate dielectric 310 and dielectric spacers 220.

As in the previous embodiment, gate spacer 510 can be formed within gate cut region by depositing a blanket layer of dielectric material and then planarizing the gate spacer 510 via CMP to recess the top of the gate spacer to approximately the same height as the interlayer dielectric 230 and the functional gate structure. A gate cap 520 can then be formed over the gate spacer 510 and the functional gate structure. The gate cap 520 may comprise a dielectric material such as, for example, silicon dioxide, silicon nitride or a dielectric metal oxide, which may be the same as or different from the gate spacer material.

Alternatively, the gate spacer 510 and the gate cap 520 may be formed simultaneously, i.e., by depositing a blanket layer of dielectric material and then planarizing.

Layout dependent effects can have a significant impact on device performance. Conventional replacement metal gate (RMG) processes require PC-past-RX to be at least twice the gate stack thickness because the gate stack materials are deposited on the gate spacers as well as on the fins. Thus, as seen in the calculation above, this requires PC-past-RX to be at least 30 nm for a typical gate stack architecture to obtain a uniform work function.

However, if the gate cut is performed post-RMG as disclosed in the instant application, the PC-past-RX length can be scaled to the thickness of the gate stack, thereby reducing PC end parasitic capacitance and improving device performance. Specifically, gate end capacitance can be decreased by cutting the gate as close as possible to the fin.

In embodiments, the gate stack integration is completed first, and then the gates are cut using a lithographically-defined CT mask and selective etching of the gate stack metals, and optically the gate dielectric. The selective etch allows the cut to be located as close as possible to the fins without attacking the source and drain epitaxial doping layers, even when the cut opening overlaps with these epitaxial layers.

As used herein, the singular forms “a,” “an” and “the” include plural referents unless the context clearly dictates otherwise. Thus, for example, reference to a “gate metal” includes examples having two or more such “gate metals” unless the context clearly indicates otherwise.

Unless otherwise expressly stated, it is in no way intended that any method set forth herein be construed as requiring that its steps be performed in a specific order. Accordingly, where a method claim does not actually recite an order to be followed by its steps or it is not otherwise specifically stated in the claims or descriptions that the steps are to be limited to a specific order, it is no way intended that any particular order be inferred. Any recited single or multiple feature or aspect in any one claim can be combined or permuted with any other recited feature or aspect in any other claim or claims.

It will be understood that when an element such as a layer, region or substrate is referred to as being formed on, deposited on, or disposed “on” or “over” another element, it can be directly on the other element or intervening elements may also be present. In contrast, when an element is referred to as being “directly on” or “directly over” another element, no intervening elements are present.

While various features, elements or steps of particular embodiments may be disclosed using the transitional phrase “comprising,” it is to be understood that alternative embodiments, including those that may be described using the transitional phrases “consisting” or “consisting essentially of,” are implied. Thus, for example, implied alternative embodiments to a gate dielectric that comprises a high-k oxide include embodiments where a gate dielectric consists essentially of a high-k oxide and embodiments where a gate dielectric consists of a high-k oxide.

It will be apparent to those skilled in the art that various modifications and variations can be made to the present invention without departing from the spirit and scope of the invention. Since modifications, combinations, sub-combinations and variations of the disclosed embodiments incorporating the spirit and substance of the invention may occur to persons skilled in the art, the invention should be construed to include everything within the scope of the appended claims and their equivalents.

1. A method of forming a semiconductor structure, comprising:
providing a structure comprising a gate cavity exposing respective portions of adjacent parallel fins disposed on a substrate, wherein the gate cavity is peripherally bounded by a dielectric spacer;
depositing a gate structure within the gate cavity, the gate structure comprising a gate dielectric formed over sidewalls and a bottom of the gate cavity and a gate electrode formed over the gate dielectric, wherein sidewalls of the dielectric spacer contact vertical portions of the gate dielectric;
depositing a conductive material over the gate electrode to completely fill the gate cavity;
selectively etching a portion of the conductive material and an underlying horizontal portion of the gate electrode to form a gate cut region solely between a pair of the adjacent fins, wherein the pair of the adjacent fins remains covered by the conductive material; and
depositing a dielectric material into the gate cut region to form an isolation region within the gate cavity, wherein the isolation region contacts cut edges of the gate electrode and is bounded by the dielectric spacer.

2. The method of claim 1, further comprising selectively etching the gate dielectric.

3. (canceled)

4. The method of claim 1, wherein the selective etch does not etch the dielectric spacer.

5. The method of claim 1, wherein the selective etch does not etch the fins.

6. The method of claim 1, further comprising depositing an epitaxial layer over the fins prior to depositing the gate structure.

7. The method of claim 6, wherein the selective etch does not etch the fins or the epitaxial layer.

8. The method of claim 1, wherein the dielectric material is formed over exposed sidewalls of the conductive material within the gate cut region, over an exposed surface of the gate dielectric at a bottom of the gate cut region, and over the cut edges of the gate electrode adjacent the conductive material and the gate dielectric.

9. The method of claim 1, wherein the selective etch removes the conductive material, the gate electrode, and the gate dielectric to form the gate cut region.

10. The method of claim 9, wherein the dielectric material is formed over exposed sidewalls of the conductive material within the gate cut region, over an exposed surface of the substrate at a bottom of the gate cut region, and over the cut edges of the gate electrode and the gate dielectric adjacent the conductive material and the substrate.

11. The method of claim 1, wherein a distance from the isolation region to at least one of the adjacent fins is less than 30 nm.

12. The method of claim 1, further comprising recessing a height of the conductive material, the gate electrode, and optionally the gate dielectric to below a height of the dielectric spacer.

13. The method of claim 12, wherein the depositing the dielectric material comprises forming the isolation region within the gate cut region and forming a gate cap over the conductive material and the gate structure.

14. The method of claim 13, further comprising planarizing the gate cap.

15.-18. (canceled)

19. The method of claim 1, wherein a distance from the isolation region to at least one of the pair of the adjacent fins is less than 30 nm.

20. (canceled)

21. The method of claim 1, further comprising:
forming a sacrificial gate that is peripherally bounded by the dielectric spacer, wherein the sacrificial gate straddling the respective portions of the fins;
forming an interlayer dielectric over portions of the fins that are not covered by the sacrificial gate or the dielectric spacer; and
removing the sacrificial gate to provide the gate cavity.
